(19) United States
(12) Patent Application Publication
(10) Pub. No.: US 2016/0254220 A1
(43) Pub. Date: Sep. 1, 2016

(54) LOW WARPING CORELESS SUBSTRATE AND SEMICONDUCTOR ASSEMBLY USING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/047,566

(22) Filed: Feb. 18, 2016

Related U.S. Application Data
(60) Provisional application No. 62/121,450, filed on Feb. 26, 2015.

(51) Int. Cl. H01L 23/498; H05K 1/11; H01L 23/00; H05K 1/02

(52) U.S. Cl. CPC H01L 23/49822; H05K 1/0271; H05K 1/111; H01L 23/49811; H01L 23/562

(57) ABSTRACT

A coreless substrate includes a build-up circuitry, a warping controller and an optional stiffener. The warping controller is adhered to the solder ball attachment side of the build-up circuitry and provides mechanical support for the coreless substrate, whereas the optional stiffener is positioned around peripheral edges of the coreless substrate at the chip attachment side of the build-up circuitry and provides mechanical support for the peripheral area of the coreless substrate.

### CROSS REFERENCE TO RELATED APPLICATIONS

This application claims the benefit of filing date of U.S. Provisional Application Ser. No. 62/121,450 filed Feb.26, 2015. The entirety of said Provisional Applications is incorporated herein by reference.

### FIELD OF THE INVENTION

The present invention relates to a coreless substrate and, more particularly, to a coreless substrate having an anti-warping controller, and a semiconductor assembly using the same.

### DESCRIPTION OF RELATED ART

Market trends of electronic devices such as multimedia devices demand for faster and slimmer designs. One of the approaches is to interconnect semiconductor chip through a coreless substrate so that the assembled device can be thinner and signal integrity can be improved. U.S. Pat. Nos. 7,851,269, 7,902,660, 7,981,728, and 8,227,703 disclose various coreless substrates for such purpose. However, as coreless substrate tends to warp during the repeated heating and cooling in the process of manufacturing, it is not commonly adopted yet.

U.S. Pat. Nos. 9,185,799, 8,860,205, 7,981,728 and 7,902,660 intend to solve this issue but with little success. Additionally, conventional approaches by modifying resin material properties or adding a stiffener around the edges of the coreless substrate can only partially improve the general rigidity problem, but not the local warping problem, especially in the central area of the coreless substrate.

For the reasons stated above, and for other reasons stated below, an urgent need exists to develop a new coreless substrate that can address high signal integrity and low profile requirement and ensure low warping during assembly and operation.

### SUMMARY OF THE INVENTION

A primary objective of the present invention is to provide a coreless substrate in which an anti-warping controller is used to provide mechanical support for the chip attachment area of the coreless substrate, thereby improving the mechanical reliability of the coreless substrate.

Another objective of the present invention is to provide a coreless substrate in which a build-up circuitry is used to offer the shortest possible interconnection length for the coreless substrate, thereby reducing the inductance and improving the electrical performance of the assembly.

In accordance with the foregoing and other objectives, the present invention provides a low warping coreless substrate that includes a build-up circuitry and an anti-warping controller. In a preferred embodiment, the build-up circuitry provides electrical contacts at its top side for chip connection and at its bottom side for next level assembly connection; and the anti-warping controller is attached to the bottom side of the build-up circuitry and aligned with the chip attachment area.

In another aspect, the present invention provides a low warping coreless substrate, including: a build-up circuitry having a top side, an opposite bottom side, bond pads at the top side, and contact pads at the bottom side, wherein the contact pads are electrically coupled to the bond pads; and an anti-warping controller that is disposed under the bottom side of the build-up circuitry.

In yet another aspect, the present invention provides a semiconductor assembly including the aforementioned low warping coreless substrate and a semiconductor device that is disposed over the top side of the build-up circuitry and electrically coupled to the bond pads.

The low warping coreless substrate according to the present invention has numerous advantages. For instance, the anti-warping controller can provide an anti-warping platform for the build-up circuitry to resolve the local warping problem at the central area of the coreless substrate. Optionally, the coreless substrate may further have a stiffener over a peripheral area of the top side of the build-up circuitry. As a result, the optional stiffener can provide mechanical support for the peripheral area of the coreless substrate. By the mechanical robustness of the stiffener and the anti-warping controller at two opposite sides of the coreless substrate, both the general rigidity and local warping problems can be resolved.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1, 2 and 3 are cross-sectional, top and bottom perspective views, respectively, of a low warping coreless substrate in accordance with one embodiment of the present invention;

FIGS. 4 and 5 are cross-sectional and top perspective views, respectively, of a semiconductor assembly in accordance with one embodiment of the present invention;

FIG. 6 is a cross-sectional view of a laminate substrate having a bottom metal layer, a first dielectric layer and a first metal layer in accordance with one embodiment of the present invention;

FIG. 7 is a cross-sectional view showing that the structure of FIG. 6 is provided with first via openings in accordance with one embodiment of the present invention;

FIG. 8 is a cross-sectional view showing that the structure of FIG. 7 is provided with first conductive traces in accordance with one embodiment of the present invention;

FIG. 9 is a cross-sectional view showing that the structure of FIG. 8 is provided with a second dielectric layer and a second metal layer in accordance with one embodiment of the present invention;

FIG. 10 is a cross-sectional view showing that the structure of FIG. 9 is provided with second via openings in accordance with one embodiment of the present invention;

FIGS. 11, 12 and 13 are cross-sectional, top and bottom perspective views, respectively, showing that the structure of FIG. 10 is provided with second conductive traces, an alignment guide and contact pads in accordance with one embodiment of the present invention;

FIGS. 14 and 15 are cross-sectional and top perspective views, respectively, of another low warping coreless substrate in accordance with another embodiment of the present invention; and

FIGS. 16 and 17 are cross-sectional and top perspective views, respectively, of another semiconductor assembly in accordance with another embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

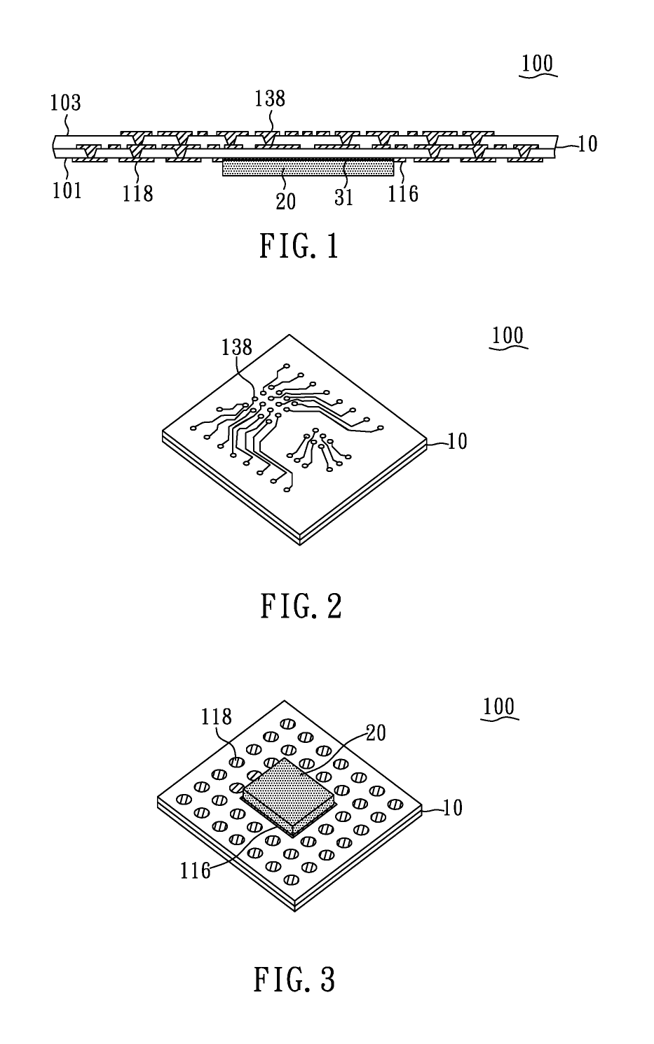

FIGS. 1, 2 and 3 are cross-sectional, top and bottom perspective views, respectively, of a low warping coreless substrate 100 that includes a build-up circuitry 10 and an anti-warping controller 20 in accordance with an embodiment of the present invention.

The build-up circuitry 10 has a bottom side 101, an opposite top side 103, contact pads 118 at the bottom side 101, and bond pads 138 at the top side 103. The contact pads 118 are formed outside a central area of the bottom side 101 and electrically coupled to the bond pads 138 by vertical and lateral routings. In this illustration, the contact pads 118 have larger pad pitch and size than those of the bond pads 138, whereas the bond pads 138 have pad pitch and size that match I/O pads of a semiconductor device to be assembled thereon. As such, a semiconductor device with fine pads can be electrically coupled to the top side 103 of the build-up circuitry 10, and next-level board assembling can be performed from the bottom side 101 of the build-up circuitry 10.

The anti-warping controller 20 is disposed under the bottom side 101 of the build-up circuitry 10 and covers the central area of the bottom side 101. The anti-warping controller 20 typically is made of high elastic modulus material (5 GPa to 500 GPa), such as ceramic, graphite, glass, metals or alloys. A resin/ceramic composite material such as molding compound also may be used for the anti-warping controller 20. Preferably, the anti-warping controller 20 has low coefficient of thermal expansion (comparable to Si around 3 ppm/K). Further, the thickness of the anti-warping controller 20 preferably ranges from 0.1 to 1.0 mm. As a result, the anti-warping controller 20 can provide mechanical support for the central area. In this illustration, the build-up circuitry 10 further has an alignment guide 116 that projects from the bottom side 101 thereof and laterally surrounds the central area. Accordingly, when the anti-warping controller 20 is attached to the central area of the bottom side 101 using an adhesive 31, the placement accuracy of the anti-warping controller 20 can be provided by the alignment guide 116.

The alignment guide 116 extends beyond the attached surface of the anti-warping controller 20 in the downward direction and is located beyond and laterally aligned with the four lateral surfaces of the anti-warping controller 20 in the lateral directions. As a result, the anti-warping controller 20 can be confined at the central area by the alignment guide 116 laterally aligned with and in close proximity to peripheral edges of the anti-warping controller 20. Preferably, a gap in between the anti-warping controller 20 and the alignment guide 116 is in a range of about 25 to 100 microns. The anti-warping controller 20 can also be attached without the alignment guide 116.

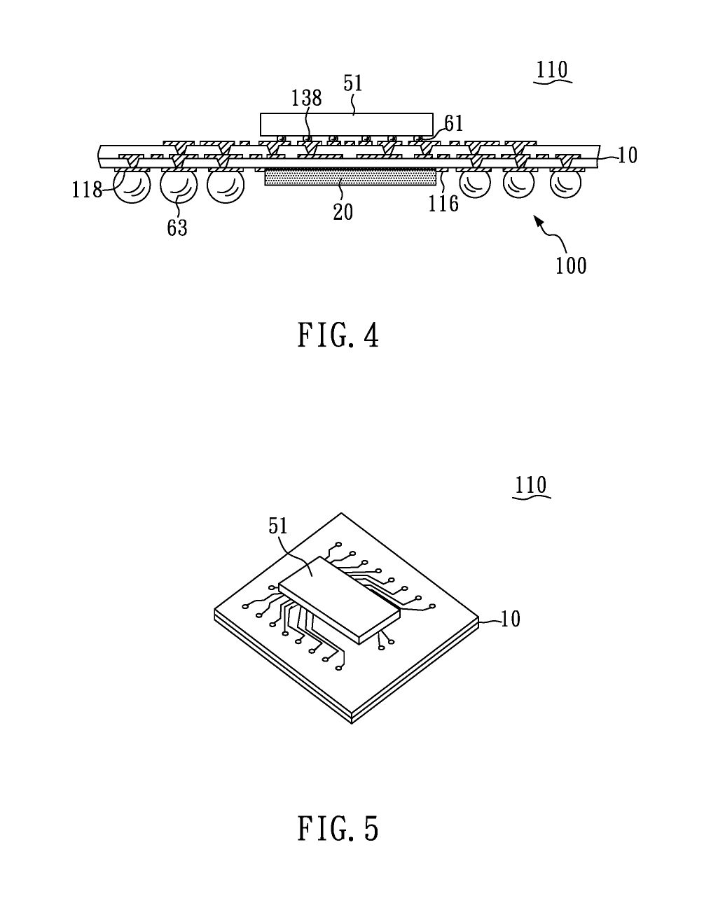

FIGS. 4 and 5 are cross-sectional and top perspective views, respectively, of a semiconductor assembly 110 with a semiconductor device 51, illustrated as a chip, mounted on the low warping coreless substrate 100 illustrated in FIGS. 1, 2 and 3. The semiconductor device 51 is flip-chip mounted on the bond pads 138 of the build-up circuitry 10 via solder bumps 61. In this illustration, the anti-warping controller 20 is aligned with the chip attachment area and is thinner than solder balls 63 attached on the contact pads 118 of the build-up circuitry 10. As a result, the anti-warping controller 20 does not interfere with next level assembly.

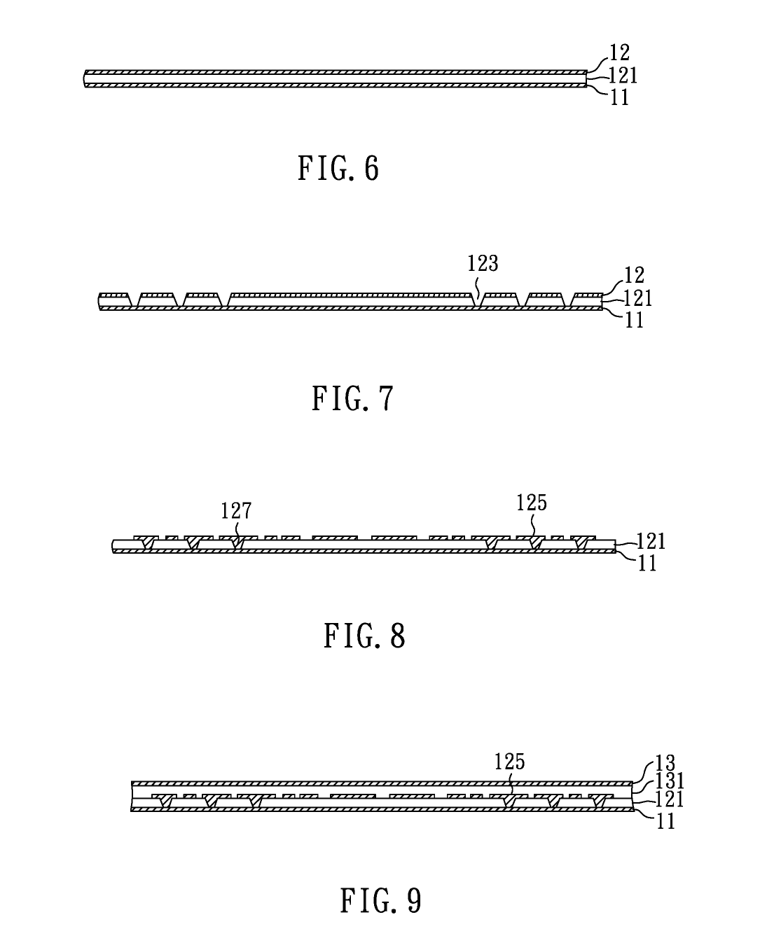

In the present invention, the build-up circuitry 10 can be fabricated by any method, and the following steps shown in FIGS. 6-13 are provided merely for exemplary illustration.

FIG. 6 is a cross-sectional view of a laminate substrate that includes a bottom metal layer 11, a first dielectric layer 121 and a first metal layer 12. The first dielectric layer 121 contacts and is sandwiched between the bottom metal layer 11 and the first metal layer 12, and typically has a thickness of 50 microns. The first dielectric layer 121 can be made of epoxy resin, glass-epoxy, polyimide, or the like. The bottom metal layer 11 and the first metal layer 12 typically are made of copper.

FIG. 7 is a cross-sectional view of the structure provided with first via openings 123. The first via openings 123 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The first via openings 123 extend through the first metal layer 12 and the first dielectric layer 121 and are aligned with selected portions of the bottom metal layer 11.

Referring now to FIG. 8, first conductive traces 125 are formed on the first dielectric layer 121 by metal deposition and metal patterning process. The first conductive traces 125 extend from the bottom metal layer 11 in the upward direction, fill up the first via openings 123 to form first conductive vias 127 in direct contact with the bottom metal layer 11, and extend laterally on the first dielectric layer 121. As a result, the first conductive traces 125 can provide horizontal signal routing in both the X and Y directions and vertical routing through the first via openings 123.

The first conductive traces 125 can be deposited as a single layer or multiple layers by any of numerous techniques, such as electroplating, electroless plating, evaporating, sputtering, or their combinations. For instance, they can be deposited by first dipping the structure in an activator solution to render the first dielectric layer 121 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the first conductive traces 125 by any of numerous techniques including wet etching, electro-chemical etching, laser-assist etching, and their combinations, with an etch mask (not shown) thereon that defines the first conductive traces 125.

FIG. 9 is a cross-sectional view of the structure with a second dielectric layer 131 and a second metal layer 13 laminated/coated on the first dielectric layer 121 and the first conductive traces 125 from above. The second dielectric layer 131 contacts and is sandwiched between the first dielectric layer 121/the first conductive traces 125 and the second metal layer 13. The second dielectric layer 131 can be formed of epoxy resin, glass-epoxy, polyimide or the like, and typically has a thickness of 50 microns. The second metal layer 13 typically is a copper layer.

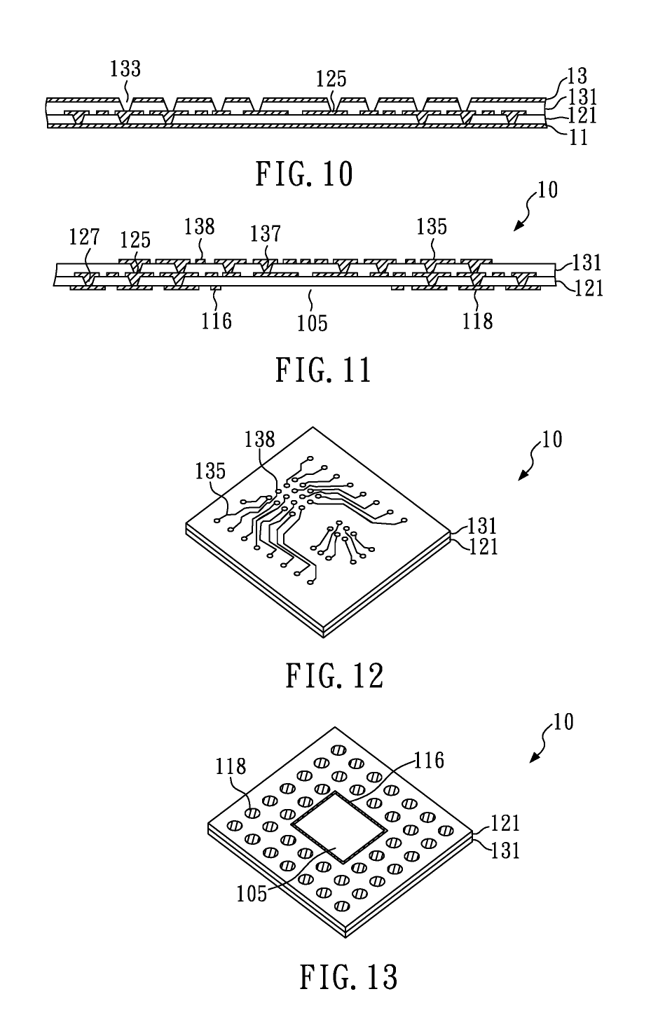

FIG. 10 is a cross-sectional view of the structure provided with the second via openings 133 to expose selected portions of the first conductive traces 125. The second via openings 133 extend through the second metal layer 13 and the second dielectric layer 131, and are aligned with selected portions of the first conductive traces 125. Like the first via openings 123, the second via openings 133 can be formed by any of numerous techniques including laser drilling, plasma etching and photolithography and typically have a diameter of 50 microns.

Referring now to FIG. 11, second conductive traces 135 are formed on the second dielectric layer 131 by metal deposition and metal patterning process. The second conductive traces 135 extend from the first conductive traces 125 in the upward direction, fill up the second via openings 133 to form second conductive vias 137 in direct contact with the first conductive traces 125, and extend laterally on the second dielectric layer 131. As shown in FIG. 12, the second conductive traces 135 include a patterned array of bond pads 138 that match chip I/O pads of a semiconductor device to be mounted thereon.

Also shown in FIGS. 11 and 13 are an alignment guide 116 and contact pads 118 formed on the lower side of the first dielectric layer 121 by metal patterning process of the bottom metal layer 11. The alignment guide 116 projects from the lower side of the first dielectric layer 121 and formed around the central area 105. The contact pads 118 are formed outside the central area 105 and electrically coupled to and contact the first conductive vias 127. In this embodiment, as the alignment guide 116 and the contact pads 118 are formed by patterning of the same metal layer, the alignment guide 116 and the contact pads 118 are made of the same material and have the same thickness. However, in some cases, the alignment guide 116 and the contact pads 118 may be made of different material and have different thickness. For instance, the alignment guide 116 may be made of a solder mask or photo resist and have a larger thickness than the contact pads 118.

### Embodiment 2

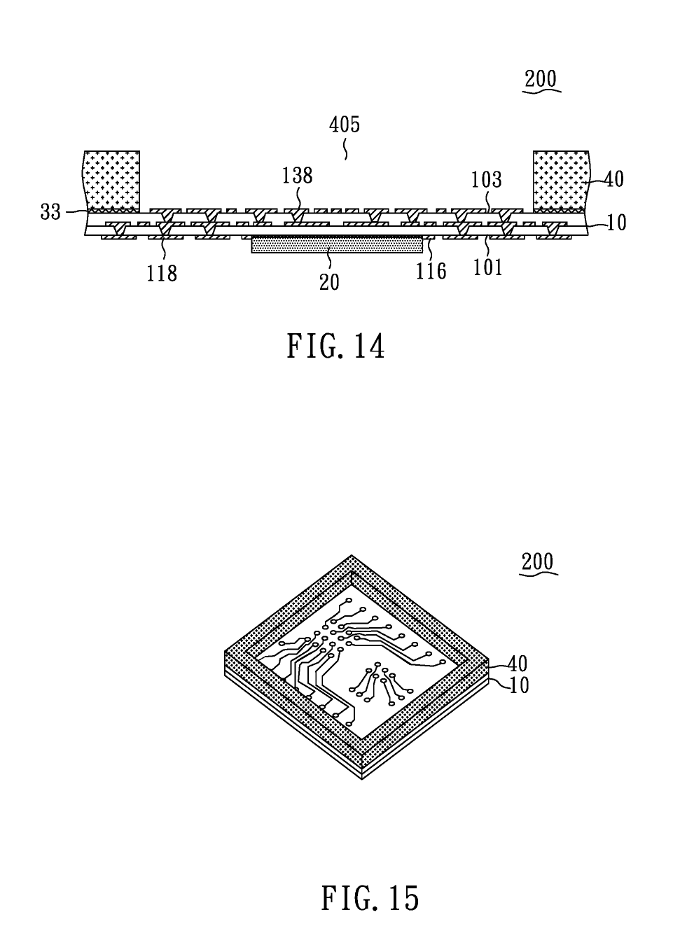

FIGS. 14 and 15 are cross-sectional and top perspective views, respectively, of another low warping coreless substrate 200 that further includes a stiffener in accordance with another embodiment of the present invention.

In this embodiment, the low warping coreless substrate 200 is similar to that illustrated in Embodiment 1, except that a stiffener 40 is further disposed over the top side 103 of the build-up circuitry 10. The stiffener 40 has a through opening 405 that extends through the stiffener 40 between top and bottom sides thereof, and is attached to the top side 103 of the build-up circuitry 10 using an adhesive 33. The stiffener 40 covers a peripheral edge of the top side 103 of the build-up circuitry 10, and the bond pads 138 of the build-up circuitry 10 are aligned with and exposed from the through opening 405 of the stiffener 40 from above. The stiffener 40 can be made of ceramic, metal, resin, composites of metal, or any other material which has enough mechanical robustness. As a result, the stiffener 40 provides mechanical support for the peripheral area of the coreless substrate, whereas the anti-warping controller 20 centrally aligned with the through opening 405 of the stiffener 40 provides mechanical support for the central area of the coreless substrate. The dual support from the anti-warping controller 20 and the stiffener 40 at two opposite sides of the coreless substrate 200 can effectively prevent the coreless substrate 200 from warping.

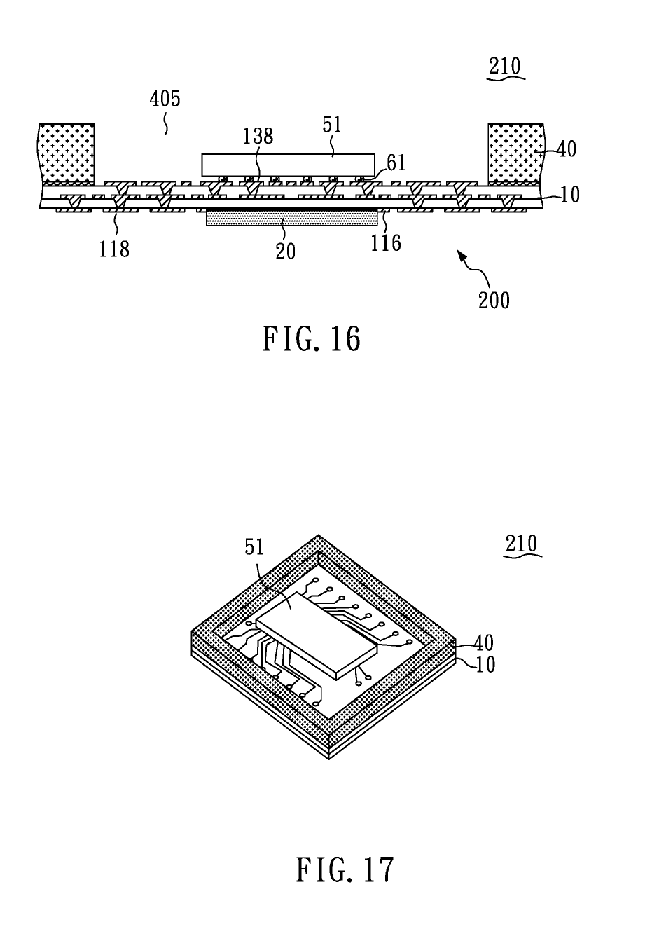

FIGS. 16 and 17 are cross-sectional and top perspective views, respectively, of a semiconductor assembly 210 with a semiconductor device 51, illustrated as a chip, mounted on the low warping coreless substrate illustrated in FIGS. 14 and 15. The semiconductor device 51 is disposed within the through opening 405 of the stiffener 40, and is flip-chip mounted on the bond pads 138 of the build-up circuitry 10 via solder bumps 61.

The coreless substrate and assemblies described above are merely exemplary. Numerous other embodiments are contemplated. In addition, the embodiments described above can be mixed-and-matched with one another and with other embodiments depending on design and reliability considerations. For instance, the stiffener may include multiple through openings arranged in an array and each through opening corresponds to an anti-warping controller. Also, additional alignment guides may be further provided and laterally aligned with the additional anti-warping controllers.

As illustrated in the aforementioned embodiments, a distinctive low warping coreless substrate is configured and includes a build-up circuitry, an anti-warping controller, and optionally a stiffener.

The build-up circuitry can have any routing/interconnect structure without a core layer, and provides electrical contacts at its top side for chip connection and at its bottom side for next level assembly or another device connection. In a preferred embodiment, the build-up circuitry includes bond pads at its top side that match chip I/O pads, and contact pads at its bottom side that have a larger pad size than that of the bond pads and match terminal pads of the next level assembly or another device. As such, a semiconductor device with fine pads can be electrically coupled to the bond pads, whereas the next level assembly or another device can be assembled to the contact pads and electrically connected to the semiconductor device through the build-up circuitry. Specifically, the build-up circuitry can include a dielectric layer, and conductive traces that fill up via openings in the dielectric layer to form conductive vias in direct contact with the contact pads at the bottom side of the dielectric layer and laterally extend on the dielectric layer. The build-up circuitry can further include additional dielectric layers, additional via openings, and additional conductive traces if needed for further signal routing. The dielectric layer and the conductive traces are serially formed in an alternate fashion, and the uppermost conductive traces include a patterned array of the bond pads and are electrically coupled to the contact pads at the bottom side of the lowermost dielectric layer through the conductive vias as vertical connection.

The anti-warping controller can be attached to the bottom side of the build-up circuitry using an adhesive to provide mechanical support for the central area of the coreless substrate. In a preferred embodiment, the anti-warping controller is aligned with the attachment area of the semiconductor device electrically coupled to the bond pads and is thinner than solder balls to be attached on the contact pads, so that the anti-warping controller does not interfere with next level assembly. The anti-warping controller can have a thickness in a range of 0.1 mm to 1.0 mm and may be made of high elastic modulus material (5 GPa to 500 GPa), such as ceramic, graphite, glass, metals or alloys. A resin/ceramic composite material such as molding compound also may be used for the anti-warping controller. Preferably, the anti-warping controller has low coefficient of thermal expansion (comparable to Si around 3 ppm/K). In the aspect of the build-up circuitry further including an alignment guide, the placement accuracy of the anti-warping controller can be provided by the alignment guide that projects from the bottom side of the build-up circuitry and is laterally aligned with and surrounds the peripheral edges of the anti-warping controller. In a preferred embodiment, the alignment guide is simultaneously formed while forming the contact pads and contacts and extends from the lowermost dielectric layer of the build-up circuitry and extends beyond the attached surface of the anti-warping controller. As such, the optional alignment guide in close proximity to peripheral edges of the anti-warping controller can confine the anti-warping controller at the predetermined location. The alignment guide can have various patterns against undesirable movement of the anti-warping controller. For instance, the alignment guide can include a continuous or discontinuous strip or an array of posts and be laterally aligned with four lateral surfaces of the anti-warping controller to define an area with the same or similar topography as the anti-warping controller. Specifically, the alignment guide can be aligned along and conform to four sides, two diagonal corners or four corners of the anti-warping controller. As a result, the alignment guide located beyond the anti-warping controller can prevent the undesired lateral displacement of the anti-warping controller. Also, the attachment of the anti-warping controller can be executed without the alignment guide.

The optional stiffener has a through opening between top and bottom sides thereof, and may be a single or multi-layer structure optionally with embedded single-level conductive traces or multi-level conductive traces. In a preferred embodiment, the stiffener is disposed over the top side of the build-up circuitry and covers a peripheral area of the top side, and the bond pads of the build-up circuitry and the anti-warping controller are aligned with the through opening of the stiffener. The stiffener can be made of any material which has enough mechanical robustness, such as metal, composites of metal, ceramic, resin or other non-metallic materials. Accordingly, the stiffener can provide mechanical support for the peripheral area of the coreless substrate to suppress warping and bending of the coreless substrate.

The semiconductor device can be a packaged or unpackaged chip. For instance, the semiconductor device can be a bare chip, or a wafer level packaged die, etc. Alternatively, the semiconductor device can be a stacked-die chip.

The term “cover” refers to incomplete or complete coverage in a vertical and/or lateral direction. For instance, the anti-warping controller covers the bottom side of the build-up circuitry regardless of whether another element such as the adhesive is between the anti-warping controller and the build-up circuitry.

The phrases “mounted on” and “attached on” include contact and non-contact with a single or multiple element(s). For instance, the anti-warping controller can be attached on the bottom side of the build-up circuitry regardless of whether it contacts the build-up circuitry or is separated from the build-up circuitry by an adhesive.

The phrase “aligned with” refers to relative position between elements regardless of whether elements are spaced from or adjacent to one another or one element is inserted into and extends into the other element. For instance, the alignment guide is laterally aligned with the anti-warping controller since an imaginary horizontal line intersects the alignment guide and the anti-warping controller, regardless of whether another element is between the alignment guide and the anti-warping controller and is intersected by the line, and regardless of whether another imaginary horizontal line intersects the anti-warping controller but not the alignment guide or intersects the alignment guide but not the anti-warping controller Likewise, the anti-warping controller is aligned with the through opening of the stiffener.

The phrase “in close proximity to” refers to a gap between elements not being wider than the maximum acceptable limit. As known in the art, when the gap between the anti-warping controller and the alignment guide is not narrow enough, the anti-warping controller may not be accurately confined at a predetermined location. The maximum acceptable limit for a gap between the anti-warping controller and the alignment guide can be determined depending on how accurately it is desired to dispose the anti-warping controller at the predetermined location. Thereby, the description “the alignment guide is in close proximity to peripheral edges of the anti-warping controller” means that the gap between the peripheral edges of the anti-warping controller and the alignment guide is narrow enough to prevent the location error of the anti-warping controller from exceeding the maximum acceptable error limit. For instance, the gaps in between the anti-warping controller and the alignment guide may be in a range of about 25 to 100 microns.

The phrases “electrically connected” and “electrically coupled” refer to direct and indirect electrical connection. For instance, the first conductive traces directly contact and are electrically connected to the contact pads and the second conductive traces are spaced from and electrically connected to the contact pads by the first conductive traces.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A low warping coreless substrate, comprising:
a build-up circuitry having a top side, an opposite bottom side, bond pads at the top side, and contact pads at the bottom side, wherein the contact pads are electrically coupled to the bond pads; and
an anti-warping controller that is disposed under the bottom side of the build-up circuitry.

2. The low warping coreless substrate of claim 1, wherein the anti-warping controller has an elastic modulus of 5 GPa or more.

3. The low warping coreless substrate of claim 1, wherein the build-up circuitry further has an alignment guide that projects from the bottom side of the build-up circuitry and is laterally aligned with and surrounds peripheral edges of the anti-warping controller.

4. The low warping coreless substrate of claim 1, further comprising a stiffener that has a through opening and is disposed over the top side of the build-up circuitry and covers a peripheral area of the top side, wherein the bond pads of the build-up circuitry and the anti-warping controller are aligned with the through opening of the stiffener.

5. The low warping coreless substrate of claim 1, wherein the contact pads have a larger pad size than that of the bond pads.

6. The low warping coreless substrate of claim 1, wherein the anti-warping controller covers a central area of the bottom side of the build-up circuitry whereas the contact pads are outside the central area of the bottom side of the build-up circuitry.

7. A semiconductor assembly, comprising:
the low warping coreless substrate of claim 1; and
a semiconductor device that is disposed over the top side of the build-up circuitry and electrically coupled to the bond pads.

8. The semiconductor assembly of claim 7, wherein the anti-warping controller has an elastic modulus of 5 GPa or more.

9. The semiconductor assembly of claim 7, wherein the coreless substrate further has an alignment guide that projects from the bottom side of the build-up circuitry and is laterally aligned with and surrounds peripheral edges of the anti-warping controller.

10. The semiconductor assembly of claim 7, further comprising a stiffener that has a through opening and is disposed over the top side of the build-up circuitry and covers a peripheral area of the top side, wherein the bond pads of the build-up circuitry and the anti-warping controller are aligned with the through opening of the stiffener.

11. The semiconductor assembly of claim 7, wherein the contact pads have a larger pad size than that of the bond pads.
